(19) United States
(12) Patent Application Publication
(10) Pub. No.: US 2002/0048715 A1
(43) Pub. Date: Apr. 25, 2002

(54) Photoresist adhesive and method

(76) Inventor: Bret Walczynski, Duluth, MN (US)

Correspondence Address: MERCHANT & GOULD PC, P.O. BOX 2903, MINNEAPOLIS, MN, 55402-0903, US

(21) Appl. No.: 09/924,742

(22) Filed: Aug. 8, 2001

Related U.S. Application Data
(60) Provisional application No. 60/223,935, filed on Aug. 9, 2000.

(51) Int. Cl. G03C 1/76; G03F 7/11

(52) U.S. Cl. 430/256; 430/270.1; 430/271.1; 430/320; 430/523

(57) ABSTRACT

An improved method and product for securing a photoresist laminate to a substrate for abrasive blasting is disclosed. The improved method and product allow fast, easy application of a photoresist laminate to a substrate with minimal mess.

### FIELD OF THE INVENTION

The present invention is directed to methods and materials for use in photoresist applications for abrasive processes. In particular, the present invention is directed to adhesives and methods of using the adhesive for photoresist etching processes.

### BACKGROUND

Surface treatment by particulate abrasion is a known process, and is done in primarily two forms: the first involves the application of direct physical pressure on the particulate media and rubbing the media across the target surface, e.g., grinding, sanding, polishing, etc.; and the second generally involves the blasting of the target surface with air-entrained particulate media, e.g., sandblasting, grit blasting, etc.

Sandblasting technology has been used for a number of years to decorate the surface of articles in a predetermined pattern. To achieve this decoration, particulate abrasive media such as steel grit, slag, sand and other forms of silicone oxide, and aluminum oxide are propelled at high velocities against the target surface. In order to control the areas of the target surface which are actually abraded by the blasting media, a patterned mask is applied to the surface.

In the past, such masks were prepared manually from rubber, paper, or other material which could withstand penetration by the abrasive media, and they were applied to the target surface using a liquid adhesive, carefully applied to the mask itself. Any adhesive which extended into the void areas of the mask was detrimental, as it often acted as an extension of the mask.

A more recent innovation in sandblasting operations is the use of photoimageable masks or photoresists. These photoresists comprise a photosensitive polymeric material which, upon selective exposure to light of a particular wavelength range, forms regions of two distinct types: those which are removable by a developer liquid and those which are unaffected by the developer. These removable and unremovable regions then form void areas and mask areas after developing. When the photoresist is applied to a target surface, the void areas allow the particulate abrasive media to strike the target surface, while the mask areas protect the underlying target surface from the particulate media.

There have been a number of different approaches to the problem of attaching the photoresist to the target surface. One approach is exemplified by Nakamura et al., U.S. Pat. Nos. 4,456,680 and 4,587,186, wherein the photoresist itself exhibits pressure sensitive adhesive properties. However, this approach requires the use of a liquid photosensitive material and careful preparation of the pressure sensitive adhesive photoresist. This involved preparation of the photoresist requires the user to be rather sophisticated and essentially precludes the use of the technology by small job shops.

Another approach requires the use of a liquid pressure sensitive adhesive forming composition which can be applied to the photoresist mask as a discrete layer. Again, if these pressure sensitive adhesive products are not carefully applied to the photoresist, they can act as a photoresist themselves as discussed above. Therefore, great accuracy is needed in the application of these adhesives to the photoresist to avoid overshoot of the adhesive into the void areas of the photoresist. In order to achieve this accuracy, especially in applications requiring very fine photoresists, time consuming manual application of the adhesive or an expensive adhesive application machine is required.

In addition, there are several products available on the market for general use in graphic arts. These adhesives are useful for application of photoresist masks or general mounting of graphic arts materials and include elastomer-based products such as 3M PHOTO MOUNT adhesive, available from 3M Co., and CAMIE 350, available from Camie Campbell, Inc. However, these adhesive compositions also are less than desirable. While, with the proper application weight, these adhesives may be penetrated and removed by the blasting media where exposed by the mask, the adhesives are not water redispersible. Therefore, to remove the sandblasting masks after the blasting operation, hazardous solvents are needed.

In view of the current state of the sandblasting adhesive art, there are a number of failings visible. Therefore, a new pressure sensitive adhesive useful to adhere sandblast masks to target surfaces is needed.

### SUMMARY OF THE INVENTION

The present invention is directed to a method of laminating a photoresist sheet to a substrate. In a first embodiment the method includes providing a photoresist sheet; providing a preformed adhesive sheet; providing a substrate (such as glass to be etched); applying the adhesive sheet to the substrate; and applying the photoresist sheet to the substrate to form a composite structure containing the photoresist sheet, adhesive sheet, and substrate.

In a second aspect, the invention is directed to method of laminating a photoresist sheet to a substrate. The method includes providing a photoresist sheet; providing a preformed adhesive sheet; providing a substrate; applying the adhesive sheet to the photoresist sheet; and applying the photoresist sheet to the substrate to form a composite structure containing the photoresist sheet, adhesive sheet, and substrate.

Use of the preformed adhesive sheet is advantageous because it allows the photoresist sheet or mask to be applied without mess and quickly. In addition, the thickness of the adhesive sheet can be controlled so as to prevent formation of excessively thick areas or areas of irregular thickness that inhibit uniform abrasive blasting.

The adhesive is typically pressure sensitive to allow easy application, and water soluble to allow easy clean up. However, other adhesives, particularly ones that are not water soluble, are also suitable for use with the invention. The adhesive sheet typically includes a carrier backing with the adhesive material. The carrier backing can be peeled from the adhesive. After the pre-formed adhesive and photoresist laminate have been applied to the substrate, the substrate may be treated with abrasive blasting to etch a decorative or functional pattern in the substrate.

The above summary of the present invention is not intended to describe each discussed embodiment of the present invention. This is the purpose of the figures, detailed description, and claims which follow.

### BRIEF DESCRIPTION OF THE DRAWINGS

The invention will be further understood by the attached figures, which are summarized below:

FIG. 1A shows elements of a photoresist system in accordance with the invention prior to application to a substrate.

FIG. 1B shows elements of a photoresist system in accordance with the invention after application to a substrate.

Specific modifications and alternative forms of the invention are shown in the drawings. It should be understood, however, that the invention is not limited to the particular embodiments described, but rather it is the intention to cover modifications, equivalents, and alternatives falling within the spirit and scope of the invention as described by the appended claims.

### DETAILED DESCRIPTION

The present invention is directed to a method of laminating a photoresist sheet to a substrate by using preformed adhesive sheets that contain a non-liquid adhesive. In one implementation, the method includes providing a photoresist sheet or mask layer; providing an adhesive sheet; providing a substrate; applying the adhesive sheet to the substrate; and applying the photoresist sheet to the substrate to form a composite structure containing the photoresist sheet, adhesive sheet, and substrate. In a second implementation, the invention is directed to method of laminating a photoresist sheet or mask layer to a substrate. The method includes providing a photoresist sheet; providing an adhesive sheet; providing a substrate; applying the adhesive sheet to the photoresist sheet; and applying the photoresist sheet to the substrate to form a composite structure containing the photoresist sheet, adhesive sheet, and substrate.

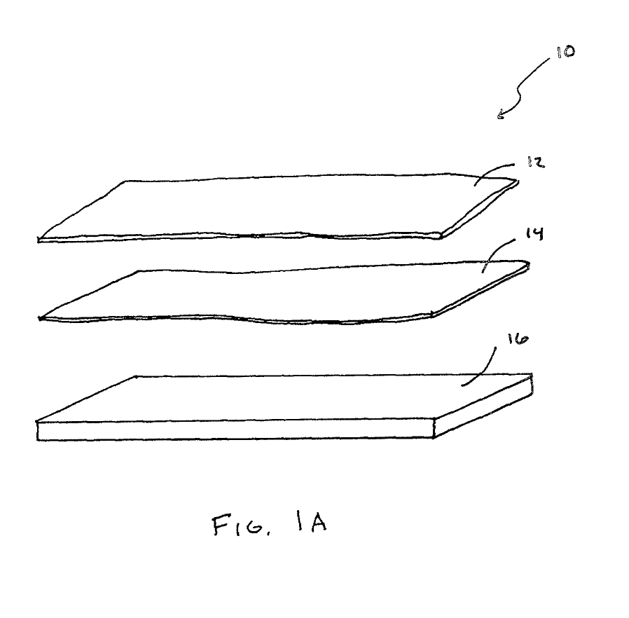

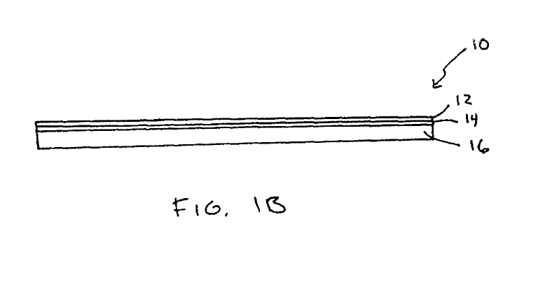

A typical configuration for the layers is shown in FIGS. 1A and 1B. The laminate composition 10 includes a photoresist sheet or mask 12, an adhesive sheet 14, and a substrate 16. These materials are shown in FIG. 1A prior to being combined, and in FIG. 1B after being combined.

Typical substrates include glass, metal, plastics and other materials that are to be etched with abrasives. Generally, the adhesive should provide sufficient strength between the photoresist mask layer and the substrate's target surface to prevent the abrasive decorating process from blasting away portions of the photoresist mask. In addition, when the photoresist mask is a laminate comprising a plurality of layers, some of which are removed after adhering of the laminate to the target surface, the adhesion between the photoresist mask layer and the target surface provided by the adhesive should be greater than the adhesion between any release liner and layer of the photoresist laminate which is in contact with the photoresist mask layer. This may be called the “transferability” of the photoresist mask. Thus, the photoresist mask is transferable if a photoresist laminate can be applied to a target surface, the laminate prepared for an abrasive blasting process, and the photoresist mask remains intact as applied on the target surface.

The adhesive is a preformed into a sheet, meaning it is applied as a sheet rather than as a liquid to the photoresist sheet or to the substrate. The preformed sheet is typically substantially uniform thickness to avoid variations in etching depth. In addition, the preformed sheet is typically thin enough to avoid significant reduction in the etching depth. Thus, the adhesive typically serves to position the photoresist mask but does not function as a mask itself. Suitable ingredients for the adhesive include poly (2-ethylhexyl acrylate); poly (n-butyl acrylate); poly (ethyl acrylate); poly (methyl acrylate), and combinations thereof.

Photoresist masks used in the practice of this invention are generally polymeric photoresists. Preferably, the photoresist mask comprises a photoresist layer as disclosed in Van Iseghem, U.S. Pat. No. 4,764,449, which is hereby incorporated by reference. This photoresist mask layer comprises a negative photosensitive composition which interacts with light of a particular wavelength to transform from a soluble state to an insoluble state. A preferred photoresist composition comprises a cross-linkable polymer composition including a polymer having pendant hydroxyl groups to react with a sufficient concentration of a photoinitiator cross-linking specie.

Preferably, the photo cross-linkable polymer composition comprises homo- and copolymers of polyvinyl alcohol. Preferred photoinitiator cross-linking species include diazonium salt photo cross-linkers. The preferred photoresist composition may also include a water insoluble film-forming polymeric binding agent such as cellulosic compounds, and water insoluble homo- and copolymers made of styrene, methylmethacrylate, vinyl acetate, vinyl butyral, ethylene, propylene, alkylene oxide monomers, and maleic anhydride. Additional components such as plasticizers, surfactants, sensitizers, etc., may also be incorporated into the photoresist mask layer.

An optional destroyable carrier film may be included and is preferably easily destroyable by sandblast media so it does not interfere with the ultimate performance of the mask. In addition, the carrier film is preferably non-elastomeric to provide dimensional stability to the laminate. Any polymeric or metallic film may be used as the carrier film if it exhibits the above characteristics. It is preferred that the carrier film be about 1 to 5 microns in thickness. This thickness provides sufficient dimensional stability while not providing too great an impediment to sandblast media. A representative, non-limiting list of useful carrier film materials includes metallic films such as copper and aluminum; polymeric films such as polyvinyl butyral, polyvinyl formal, polyethylene-vinyl acetate copolymers, polyolefins, nitrocellulose, polyvinyl chloride; and other materials such as paper.

The photoresist laminate may also include at least one release liner to protect the mask. The release liner should contact the support membrane and photosensitive layer with a surface having low surface energy. This is typically achieved by coating a film with a thin layer of a release agent or release liner such as silicone, electron beam (EB) cured release coating, polytetrafluoroethylene (PTFE), or UV curable release coating. Preferably, the release liner comprises a polyolefin film such as polypropylene, or polyethylene, a polyester film such as polyethylene terephthalate, or MYLAR.

Although the present invention has been described with reference to the above particular discussion and examples, it should be understood that those skilled in the art may make many other modifications without departing from the spirit and scope of the invention as defined by the appended claims.

What is claimed is:

1. A method of laminating a photoresist sheet to a substrate, the method comprising:
a) providing a photoresist sheet;
b) providing an adhesive sheet;
c) providing a substrate;
d) applying the adhesive sheet to the substrate;
e) applying the photoresist sheet to the substrate to form a composite structure containing the photoresist sheet, adhesive sheet, and substrate.

2. The method according to claim 1, wherein the adhesive is pressure sensitive.

3. The method according to claim 1, wherein the adhesive is water soluble.

4. The method according to claim 1, wherein the adhesive is selected from the group consisting of adhesives containing poly (2-ethylhexyl acrylate); poly (n-butyl acrylate); poly (ethyl acrylate); poly (methyl acrylate), and combinations thereof.

5. The method according to claim 1, wherein the adhesive sheet comprises a carrier backing and an adhesive material

6. The method according to claim 5, wherein the carrier backing can be peeled from the adhesive.

7. A method of laminating a photoresist sheet to a substrate, the method comprising:
a) providing a photoresist sheet;
b) providing an adhesive sheet;
c) providing a substrate;
d) applying the adhesive sheet to the photoresist sheet;
e) applying the photoresist sheet and the adhesive sheet to the substrate to form a composite structure containing the photoresist sheet, adhesive sheet, and substrate.

8. The method according to claim 7, wherein the adhesive is pressure sensitive.

9. The method according to claim 7, wherein the adhesive is water soluble.

10. The method according to claim 7, wherein the adhesive is selected from the group consisting of adhesives containing poly (2-ethylhexyl acrylate); poly (n-butyl acrylate); poly (ethyl acrylate); poly (methyl acrylate), and combinations thereof.

11. The method according to claim 7, wherein the adhesive sheet comprises a carrier backing and an adhesive material

12. The method according to claim 11, wherein the carrier backing can be peeled from the adhesive.
